(19) United States
(12) Patent Application Publication
(10) Pub. No.: US 2005/0070123 A1
(43) Pub. Date: Mar. 31, 2005

(54) Method for forming a thin film and method for fabricating a semiconductor device

(76) Inventor: Tomoyuki Hirano, Kanagawa (JP)

Correspondence Address: ROBERT J. DEPKE LEWIS T. STEADMAN;HOLLAND & KNIGHT LLC, 131 SOUTH DEARBORN, 30TH FLOOR, CHICAGO, IL, 60603, US

(21) Appl. No.: 10/927,596

(22) Filed: Aug. 26, 2004

(30) Foreign Application Priority Data
Aug. 27, 2003 (JP) JP2003-302291

(51) Int. Cl. H01L 21/3205; H01L 21/31

(52) U.S. Cl. 438/778; 438/785; 438/591

(57) ABSTRACT

By conducting a high temperature annealing in a nitrogen atmosphere at a temperature at which a hafnium silicate film undergoes no phase separation, hydrogen contained in the film is removed and prevention of boron penetration is made possible. The present invention provides a method for forming a thin film including a step of forming a hafnium silicate film on a substrate by an atomic layer deposition method and a step of carrying out thermal treatment on the hafnium silicate film at a thermal treatment temperature equal to or higher than a temperature at which hydrogen contained in the hafnium silicate film is removed and lower than a temperature at which the hafnium silicate film undergoes no phase separation, and a method for fabricating a semiconductor device for forming a gate dielectric film using the method for forming a thin film.

### CROSS REFERENCES TO RELATED APPLICATIONS

The present document is based on Japanese Priority Document JP 2003-302291, filed in the Japanese Patent Office on Aug. 27, 2003, the entire contents of which being incorporated herein by reference.

### BACKGROUND OF THE INVENTION

1. Field of the Invention

The present invention relates to a method for forming a thin film, which is advantageously used in forming a high-quality hafnium silicate film, and a method for fabricating a semiconductor device using the method for forming a thin film in a process for forming a gate dielectric film.

2. Description of Related Art

An insulated gate field effect transistor has already been on a stage in which miniaturization thereof is about to achieve a gate length of 0.1 μm. The miniaturization further increases the speed of a device, lowers the power consumption, and reduces the area occupied by a device. In addition, recently, an increased number of devices can be mounted on the same chip area, and hence an LSI itself having multiple functions has been realized. However, it is predicted that the pursuit of miniaturization will meet walls of 0.1 μm. One of the walls is the limitation of reduction of the thickness of a gate dielectric film. Conventionally, silicon oxide (SiO₂) has been used in the gate dielectric film for the reason that silicon oxide satisfies two properties indispensable for the device operation, that is, silicon oxide contains almost no fixed charge and forms almost no interface state in the boundary with Si in a channel portion. In addition, silicon oxide (SiO₂) is advantageous in that a thin film can be easily formed therefrom with excellent controllability, and therefore it is effective in miniaturizing a device.

However, silicon oxide (SiO₂) has a low dielectric constant (3.9) and, when used in transistors of a generation having a gate length of 0.1 μm or later, a silicon oxide film is required to have a thickness of 3 nm or less for satisfying the transistor performance. It is expected that a carrier directly undergoes tunneling in the silicon oxide film having the above thickness, causing a problem in that the leakage current between the gate and the substrate is increased.

For solving the problem, studies have been made on prevention of a tunneling phenomenon by using a material having a dielectric constant higher than that of silicon oxide (SiO₂) to increase the thickness of the gate dielectric film. As materials having a higher dielectric constant, metal oxide films of aluminum oxide (Al₂O₃), zirconium oxide (ZrO₂), hafnium oxide (HfO₂), and the like are studied (see, for example, Patent document 1). These films have a higher dielectric constant and hence, when obtaining the same gate capacitance, the thickness of these films can be increased several times, as compared to the thickness of the silicon oxide film, and they are considered to be promising materials which can suppress the tunneling phenomenon. However, in the production process using a polycrystalline silicon electrode used for the existing silicon oxide gate dielectric film, an activation thermal treatment (annealing) at 1,000° C. or higher is needed. In a case where this thermal treatment is applied to a high dielectric-constant film of zirconium oxide (ZrO₂), hafnium oxide (HfO₂), or the like, the poor heat resistance of a high dielectric-constant (High-k) film of zirconium oxide (ZrO₂), hafnium oxide (HfO₂), or the like causes crystallization and a silicide formation reaction with a silicon substrate, leading to a problem in that the leakage current is increased. For solving this problem, methods using Hf(Zr)SiO or Hf(Zr)SiON containing silicon and nitrogen have been developed. The use of Hf(Zr)SiO or Hf(Zr)SiON in the gate dielectric film improves the heat resistance, thus making it possible to lower the leakage current.

In addition, a gate dielectric film comprised of three hafnium oxide films stacked on one another so that the grain boundaries are discontinuous for suppressing the leakage current is disclosed, and it is disclosed that the film is subjected to high-temperature annealing in a nitrogen atmosphere at 900° C. for stabilizing the binding state or composition of the stacked three hafnium oxide films (see, for example, Patent document 2).
[Patent document 1] Japanese Patent Application Publication No. 2003-69011
[Patent document 2] Japanese Patent Application Publication No. 2003-179051

### SUMMARY OF THE INVENTION

In a case where a high dielectric-constant film (referred to as “High-k film”) is formed by a conventional technique, a fixed charge is generated at an interface between the High-k film and the Si substrate or polycrystalline silicon (Poly-Si) electrode, causing a problem in that shifting of a threshold voltage (Vth) and degrading of the mobility occur. Further, in a PMOS transistor, a problem occurs in that boron with which the gate electrode is doped penetrates the high dielectric-constant film and diffuses into the substrate side during the subsequent thermal treatment. It is known that boron penetration is suppressed by addition of nitrogen; however, in a case where nitrogen is added by the conventional technique, nitrogen enters the substrate, causing a problem in that the interface state is increased.

The method for forming a thin film of the present invention is mainly characterized by comprising the steps of: forming a hafnium silicate film on a substrate by an atomic layer deposition method; and carrying out thermal treatment on the hafnium silicate film at a thermal treatment temperature equal to or higher than a temperature at which hydrogen contained in the hafnium silicate film is removed and lower than a temperature at which the hafnium silicate film undergoes no phase separation.

The method for fabricating a semiconductor device of the present invention is mainly characterized by comprising the steps of: forming a gate dielectric film on a semiconductor substrate; forming a gate electrode on the gate dielectric film; and forming source-drain regions in the semiconductor substrate on both sides of the gate electrode, wherein the gate dielectric film is formed through the steps of: forming a hafnium silicate film on the semiconductor substrate by an atomic layer deposition method; and carrying out thermal treatment on the hafnium silicate film at a thermal treatment temperature equal to or higher than a temperature at which hydrogen contained in the hafnium silicate film is removed and lower than a temperature at which the hafnium silicate film undergoes no phase separation.

In the method for forming a thin film and method for fabricating a semiconductor device of the present invention, the hafnium silicate film is subjected to thermal treatment at a thermal treatment temperature equal to or higher than a temperature at which hydrogen contained in the hafnium silicate film is removed and lower than a temperature at which the hafnium silicate film undergoes no phase separation, and therefore hydrogen contained in the hafnium silicate film can be removed without causing the hafnium silicate film to change in phase, so that the hafnium silicate film formed suffers no boron penetration. Thus, there is obtained an advantage in that the semiconductor device can be improved in mobility and reliability.

### BRIEF DESCRIPTION OF THE DRAWINGS

The above and other objects, features and advantages of the present invention will become more apparent from the following description of the presently preferred exemplary embodiments of the invention taken in conjunction with the accompanying drawings, in which:

FIG. 1A and FIG. 1B are cross-sectional views showing a production process in an embodiment of a method for forming a thin film of the present invention;

FIG. 2 is a diagram showing a hydrogen concentration of a hafnium silicate film in a depth direction;

FIG. 3 is a diagram showing relationship between an interface state density of a hafnium silicate film and a thermal treatment temperature;

FIG. 4A to FIG. 4D are cross-sectional views showing a production process in an embodiment of a method for fabricating a semiconductor device of the present invention;

FIG. 5 is a diagram, using the thermal treatment temperature as a parameter, showing electron mobility in connection with a transistor formed by the method for fabricating a semiconductor device of the present invention; and

FIG. 6 is a diagram showing C-V (capacitance-voltage) characteristic of an insulated gate field effect transistor using a hafnium silicate film in a gate dielectric film.

### DESCRIPTION OF THE PREFERRED EMBODIMENTS

In order to improve transistor performance using a high dielectric-constant film, especially a hafnium silicate film, as a gate dielectric film, the present invention provides a method for forming a thin film, which solves a problem of boron penetration and a method for fabricating a semiconductor device using the method for forming a thin film.

### EXAMPLE 1

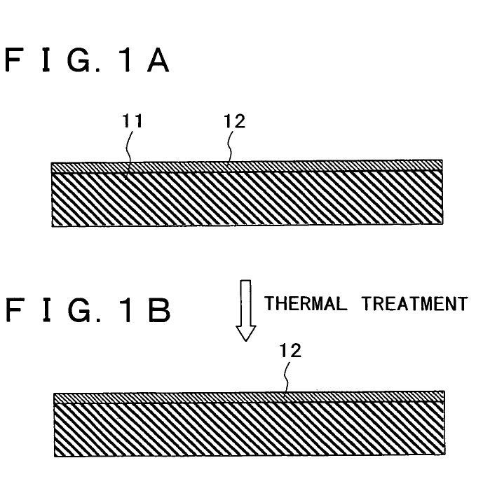

An embodiment of the method for forming a thin film and the method for fabricating a semiconductor device of the present invention will be described with reference to diagrammatic cross-sectional views of FIG. 1A and FIG. 1B.

As shown in FIG. 1A and FIG. 1B, a hafnium silicate (HfSiO) film 12 is formed on a substrate 11 by an atomic layer deposition (ALD) method using an organic raw material. In the substrate 11, a silicon substrate is used as a semiconductor substrate. The hafnium silicate film 12 is formed so that the thickness becomes, for example, 0.5 to 2.0 nm in terms of a silicon oxide film. The hafnium silicate film 12 is formed by an ALD method using an organic raw material, and hence hydrogen remains in the film. Generally, when an insulating film in which hydrogen remains is used in a gate dielectric film, a problem of so-called boron penetration occurs in that boron (B) contained in a polysilicon gate electrode penetrates the gate dielectric film and reaches the silicon substrate.

For solving the problem, as shown in FIG. 1B, the hafnium silicate film 12 is subjected to thermal treatment at a thermal treatment temperature equal to or higher than a temperature at which hydrogen contained in the hafnium silicate film 12 is removed and lower than a temperature at which the hafnium silicate film 12 undergoes no phase separation. The thermal treatment is conducted by, as an example, rapid thermal annealing (RTA) in a nitrogen atmosphere at 1,000° C. for 30 seconds. Even when the thermal treatment is conducted in a nitrogen atmosphere containing oxygen in such a slight amount that silicon in the substrate is not oxidized (for example, at an oxygen partial pressure of 6.7 Pa or less), a similar effect is obtained. Instead of the nitrogen atmosphere, an inert gas atmosphere (rare gas atmosphere) may be employed. In this case, the rare gas may contain nitrogen. It has been confirmed that the effect of the thermal treatment can be obtained at a thermal treatment temperature of 900° C. or higher.

Even if the hafnium silicate film 12 is a film containing nitrogen, the same result is obtained. Particularly, introduction of nitrogen improves the effect of suppressing boron penetration.

After forming the hafnium silicate film 12 and before performing the thermal treatment, a step for introducing nitrogen to the hafnium silicate film 12 may be performed. As an example of the method for introducing nitrogen, there can be mentioned a plasma doping technique.

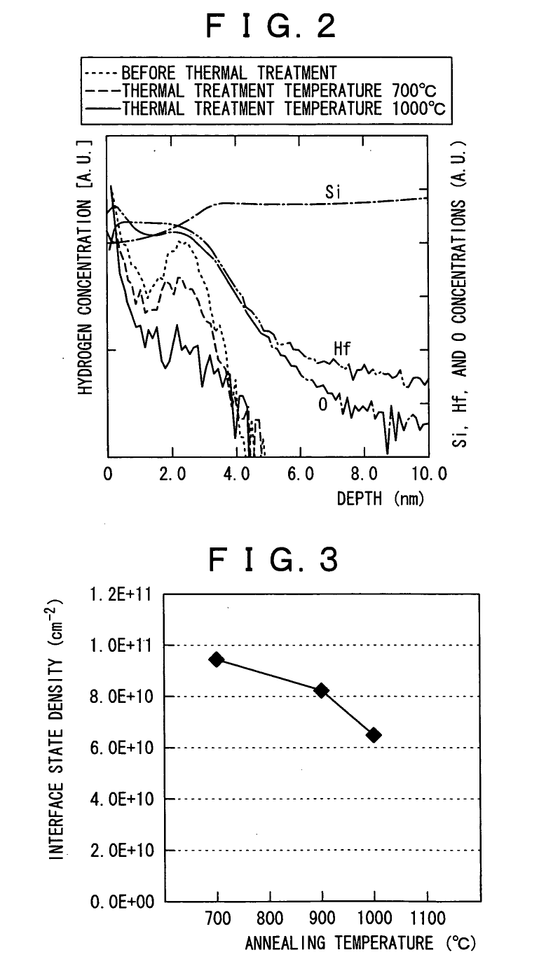

Next, the effect of the above thermal treatment is verified. FIG. 2 is a diagram showing a hydrogen concentration of a hafnium silicate film (including a hafnium silicate film containing nitrogen) in a depth direction. As shown in FIG. 2, it has been found that the hydrogen concentration is lowest when the thermal treatment is conducted by RTA at 1,000° C. for 30 seconds. On the other hand, although the effect of lowering the hydrogen concentration obtained when the thermal treatment was conducted by RTA at 700° C. for 30 seconds was more excellent than that obtained when no thermal treatment was conducted, an effect of preventing boron penetration could not be obtained. By contrast, in the present invention, by subjecting the hafnium silicate film (including a hafnium silicate film containing nitrogen) 12 to thermal treatment at a temperature equal to or higher than a temperature at which hydrogen contained in the hafnium silicate film 12 is removed and lower than a temperature at which the hafnium silicate film 12 undergoes no phase separation, the hydrogen concentration of the film could be lowered by a single digit approximately.

Although not shown, it has been confirmed that a carbon concentration of the film especially having a thickness within the range of the thickness of the film used as a gate dielectric film (thickness of 5 nm or less) is lower when the thermal treatment is conducted by RTA at 1,000° C. for 30 seconds. On the other hand, the effect of lowering the carbon concentration obtained when the thermal treatment was conducted by RTA at 700° C. for 30 seconds was only a little more excellent than that obtained when no thermal treatment was conducted. From this result, it has been found that, in the present invention, by subjecting the hafnium silicate film 12 to the thermal treatment at a thermal treatment temperature equal to or higher than a temperature at which hydrogen contained in the hafnium silicate film 12 is removed and lower than a temperature at which the hafnium silicate film 12 undergoes no phase separation, the carbon concentration of the film can be lowered.

FIG. 3 is a diagram showing relationship between an interface state density of a hafnium silicate film (including a hafnium silicate film containing nitrogen) by a charge pumping method and a thermal treatment temperature. As shown in FIG. 3, it has been found that, as the thermal treatment temperature is increased, the interface state density is lowered. Specifically, the interface state density was lowered by the thermal treatment by RTA at 900° C. for 30 seconds, and the interface state density was further lowered by the thermal treatment by RTA at 1,000° C. for 30 seconds, as compared to the interface state density by the thermal treatment by RTA at 700° C. for 30 seconds.

### EXAMPLE 2

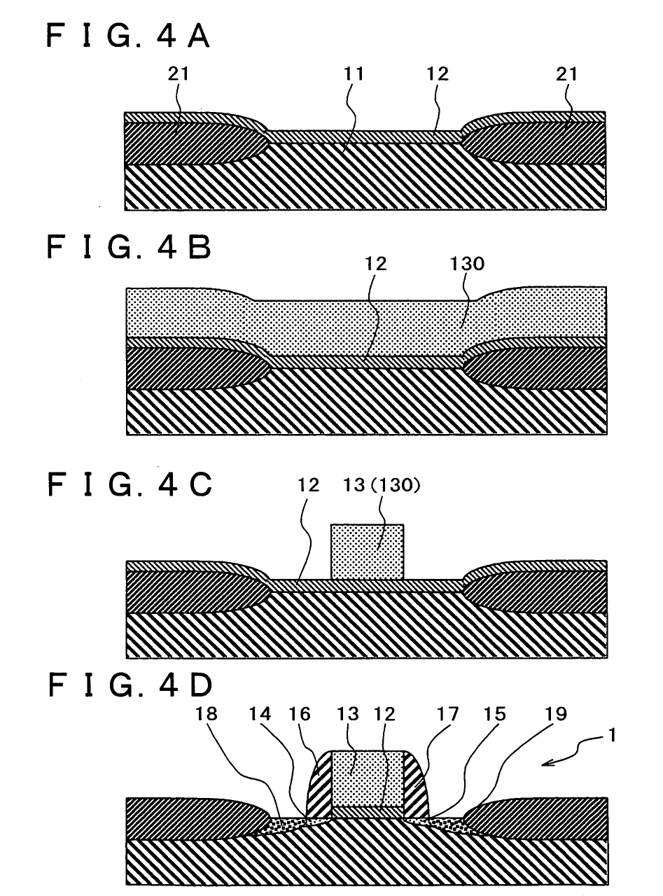

Next, an embodiment of a method for fabricating a semiconductor device of the present invention will be described with reference to diagrammatic cross-sectional views of FIG. 4A to FIG. 4D.

As shown in FIG. 4A, a hafnium silicate (HfSiO) film 12 is formed on a substrate 11 by an atomic layer deposition (ALD) method using an organic raw material. In the substrate 11, a silicon substrate is used as a semiconductor substrate. Isolation regions 21 are preliminarily formed in the substrate 11 by a local oxidation method (e.g., a LOCOS method) or an STI (shallow trench isolation) method. The hafnium silicate film 12 is formed so that the thickness becomes, for example, 0.5 to 2.0 nm in terms of a silicon oxide film. The hafnium silicate film 12 is formed by an ALD method using an organic raw material, and hence hydrogen remains in the film. Generally, when an insulating film in which hydrogen remains is used in a gate dielectric film, a problem of so-called boron penetration occurs in that boron (B) contained in a polysilicon gate electrode penetrates the gate dielectric film and reaches the silicon substrate.

For solving the problem, the hafnium silicate film 12 is subjected to thermal treatment at a thermal treatment temperature equal to or higher than a temperature at which hydrogen contained in the hafnium silicate film 12 is removed and lower than a temperature at which the hafnium silicate film 12 undergoes no phase separation. The thermal treatment is conducted by, as an example, rapid thermal annealing (RTA) in a nitrogen atmosphere at 1,000° C. for 30 seconds. Even if the thermal treatment is conducted in a nitrogen atmosphere containing oxygen in such a slight amount that silicon contained in the substrate is not oxidized (for example, at an oxygen partial pressure of 6.7 Pa or less), a similar effect is obtained. Instead of the nitrogen atmosphere, an inert gas atmosphere (rare gas atmosphere) may be employed. In this case, the rare gas may contain nitrogen. It has been confirmed that the effect of the thermal treatment can be obtained at a thermal treatment temperature of 900° C. or higher.

If the hafnium silicate film 12 is a film containing nitrogen, the same result is obtained. Particularly, introduction of nitrogen improves the effect of suppressing boron penetration.

After forming the hafnium silicate film 12 and before performing the thermal treatment, a step for introducing nitrogen to the hafnium silicate film 12 may be performed. As an example of the method for introducing nitrogen, there can be mentioned a plasma doping technique.

Next, as shown in FIG. 4B, a gate electrode material layer 130 is formed on the hafnium silicate film 12. As the gate electrode material, for example, polycrystalline silicon is used, and the film is formed so as to have a thickness of, for example, 180 nm. Then, the gate electrode material layer 130 is doped with an impurity. In a case of forming a p-type gate electrode, the layer is doped with, for example, boron, or in a case of forming an n-type gate electrode, the layer is doped with, for example, phosphorus, arsenic, or the like. As the doping method, for example, an ion implantation method can be used.

Next, as shown in FIG. 4C, the gate electrode material layer 130 is patterned using a general lithography technique and etching technique to form a gate electrode 13.

Then, as shown in FIG. 4D, the semiconductor substrate 11 on both sides of the gate electrode 13 is doped with an impurity using a known technique to form lightly doped drain (LDD) regions 14, 15. Then, sidewall spacers 16, 17 are formed on the sidewalls of the gate electrode 13. Then, source-drain regions 18, 19 are formed in the semiconductor substrate 11 on both sides of the gate electrode 13 so that the LDD regions 14, 15 respectively remain under the sidewall spacers 16, 17. As the doping technique for forming the LDD regions 14, 15 and the source-drain regions 18, 19, a general ion implantation method can be used. Then, activation annealing for the impurity is effected, thus forming a MOS field effect transistor 1.

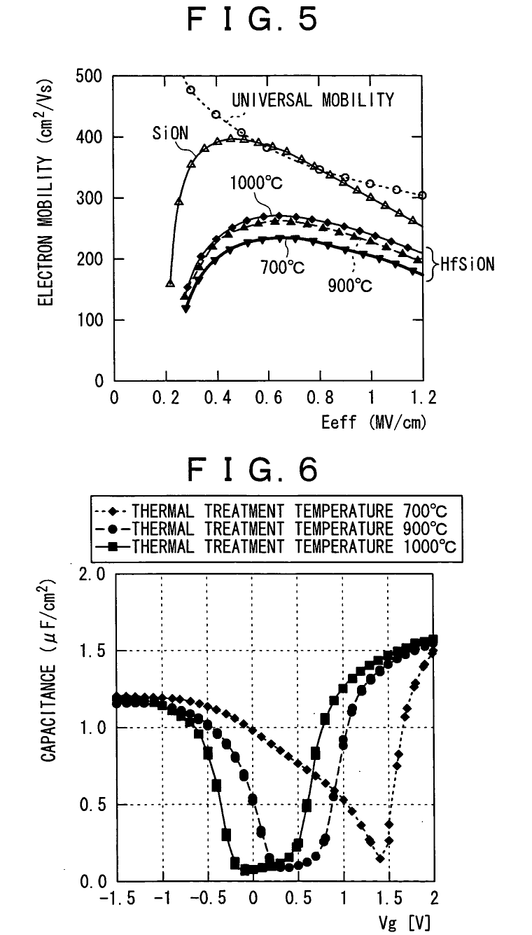

FIG. 5 is a diagram, using the thermal treatment temperature as a parameter, showing electron mobility in connection with a transistor formed by the method for fabricating a semiconductor device of the present invention. As shown in FIG. 5, it has been found that, as the thermal treatment temperature is increased, the electron mobility of the hafnium silicate film containing nitrogen is higher. Thus, by conducting the RTA treatment at a thermal treatment temperature increased to 900° C., preferably 1,000° C., the mobility of the insulated gate field effect transistor could be improved. Especially in a case of conducting the thermal treatment at 1,000° C., in the range of from 0.7 to 0.9 MV/cm with regard to the universal mobility, a mobility of about 73 to 78% can be obtained, indicating that satisfactory transistor properties can be exhibited. On the other hand, it has been found that, in a case where the thermal treatment temperature is about 700° C., a satisfactory electron mobility cannot be obtained. Therefore, for obtaining an electron mobility for achieving transistor properties, for example, when the thermal treatment time is 30 seconds, RTA is conducted at a thermal treatment temperature of 900° C. or higher, preferably 1,000° C. or higher. The upper limit is required to satisfy thermal treatment conditions (temperature and time) such that the hafnium silicate film suffers no phase change. Therefore, in a case where the thermal treatment temperature is higher than 1,000° C., the thermal treatment time is needed to be shorter than 30 seconds, and, in this case, it is necessary to prevent the hafnium silicate film from suffering a phase change.

FIG. 6 shows C-V (capacitance-voltage) characteristic of an insulated gate field effect transistor using a hafnium silicate film a in gate dielectric film. As shown in FIG. 6, it has been found that, with respect to the C-V characteristic, the gate dielectric film subjected to thermal treatment by RTA at 900° C. for 30 seconds, and further the gate dielectric film subjected to thermal treatment by RTA at 1,000° C. for 30 seconds are suppressed in shifting of the Vth in the positive direction, as compared to the gate dielectric film subjected to thermal treatment by RTA at 700° C. for 30 seconds. The reason for this is presumed that the thermal treatment at a high temperature removes hydrogen contained in the hafnium silicate film to suppress boron penetration.

In addition, in the MOS field effect transistor 1, the gate dielectric film is formed by the method for forming a thin film of the present invention, and therefore the effect described above with reference to FIG. 2 and FIG. 3 can be obtained.

The method for forming a thin film of the present invention can be applied to formation of a gate dielectric film in an insulated gate field effect transistor, and the method for fabricating a semiconductor device of the present invention can be applied to a production method of an insulated gate field effect transistor using a hafnium silicate-based film, which is a high dielectric-constant film, in a gate dielectric film.

Although the invention has been described in its preferred form with a certain degree of particularity, obviously many changes and variations are possible therein. It is therefore to be understood that the present invention may be practiced otherwise than as specifically described herein without departing from the scope and the sprit thereof.

1. A method for forming a thin film, comprising the steps of:
forming a hafnium silicate film on a substrate by an atomic layer deposition method; and
subjecting said hafnium silicate film to thermal treatment at a thermal treatment temperature equal to or higher than a temperature at which hydrogen contained in said hafnium silicate film is removed and lower than a temperature at which said hafnium silicate film undergoes no phase separation.

2. The method for forming a thin film according to claim 1, wherein said hafnium silicate film contains nitrogen.

3. The method for forming a thin film according to claim 1, further comprising, after forming said hafnium silicate film and before performing said thermal treatment, a step for introducing nitrogen to said hafnium silicate film.

4. The method for forming a thin film according to claim 1, wherein said thermal treatment is performed in a nitrogen atmosphere or an inert gas atmosphere.

5. A method for fabricating a semiconductor device, comprising the steps of:
forming a gate dielectric film on a semiconductor substrate;
forming a gate electrode on said gate dielectric film; and
forming source-drain regions in said semiconductor substrate on both sides of said gate electrode,
wherein said gate dielectric film is formed through the steps of:
forming a hafnium silicate film on said semiconductor substrate by an atomic layer deposition method; and
subjecting said hafnium silicate film to thermal treatment at a thermal treatment temperature equal to or higher than a temperature at which hydrogen contained in said hafnium silicate film is removed and lower than a temperature at which said hafnium silicate film undergoes no phase separation.

6. The method for fabricating a semiconductor device according to claim 5, wherein said hafnium silicate film contains nitrogen.

7. The method for fabricating a semiconductor device according to claim 5, further comprising, after forming said hafnium silicate film and before performing said thermal treatment, a step for introducing nitrogen to said hafnium silicate film.

8. The method for fabricating a semiconductor device according to claim 5, wherein said thermal treatment is performed in a nitrogen atmosphere or an inert gas atmosphere.
